(19) United States
(12) Patent Application Publication
(10) Pub. No.: US 2018/0254438 A1
(43) Pub. Date: Sep. 6, 2018

(54) Top Emitting OLEDs with Increased Brightness

(71) Applicant: eMagin Corporation, Hopewell Junction, NY (US)

(72) Inventors: Qi WANG, Hopewell Junction, NY (US); Evan P. DONOGHUE, Hopewell Junction, NY (US); Ilyas I. KHAYRULLIN, Hopewell Junction, NY (US); Tariq ALI, Hopewell Junction, NY (US); Kerry TICE, Hopewell Junction, NY (US); Amalkumar P. GHOSH, Hopewell Junction, NY (US)

(21) Appl. No.: 15/909,434

(22) Filed: Mar. 1, 2018

Related U.S. Application Data
(60) Provisional application No. 62/465,463, filed on Mar. 1, 2017.

(51) Int. Cl. H01L 51/52; H01L 51/50; H01L 51/00; H01L 51/56

(52) U.S. Cl. CPC H01L 51/5275; H01L 51/5056; H01L 51/5072; H01L 51/56; H01L 51/5234; H01L 51/0081; H01L 51/5206

(57) ABSTRACT

A top emitting OLED includes two organic light-extraction layers on top of an at least partially transparent cathode. At least one of the light-extraction layers comprises an electron transport material and at least one of the light-extraction layers comprises a hole transport material. In some embodiments, the electron transport material is Alq3 and the hole transport material is a triaryl amine derivative.

### STATEMENT OF RELATED CASES

This application claims priority to U.S. Pat. App. Ser. No. 62/465,463 filed Mar. 1, 2017, which is incorporated by reference herein.

### FIELD OF THE INVENTION

The present invention relates generally to top-emitting, organic light emitting diodes.

### BACKGROUND OF THE INVENTION

Top emitting organic light-emitting diode (TEOLED) is a promising technology for active matrix displays. Conventional TEOLEDs sandwich organic semiconductor layers between a metal reflector electrode (strong mirror) and a semi-transparent electrode (weak mirror), the latter of which enables the light to pass. Typically, about 80 percent of the emitted light is trapped within the TEOLED due to internal reflections. Consequently, only about 20% of the emitted light escapes as useful light.

In order to extract more light from (enhance out-coupling efficiency) an OLED, a light-extraction layer is sometimes used. In a TEOLED, the light extraction layer must be on top of the semi-transparent cathode, and due to fabrication issues, it can be problematic to include such a layer.

### SUMMARY OF THE INVENTION

The present invention provides a way to increase the out-coupling efficiency of TEOLEDs. In the illustrative embodiment, the TEOLED includes a light-extraction structure, which increases the out-coupling efficiency and therefore the brightness of a TEOLED.

The light-extraction structure functions, at least in part, as an antireflection layer. In some embodiments, the light-extraction structure comprises at least two light-extraction layers, each comprising at least one carrier-transport material. In some other embodiments, the light-extraction structure comprises a composite light-extraction layer comprising multiple carrier-transport materials.

In some embodiments of the invention, two carrier transport materials are used: an electron transport material and a hole transport material.

In a preferred embodiment, the electron transport material is Tris(8-hydroxyquinoline)aluminum(III), commonly called “Alq3,” and the hole transport material is a triaryl amine derivative, an example of which is commercially available under the brand name “EL-301” from Hodogaya Chemical USA Inc. of White Plains, N.Y.

Comparative testing has shown that an TEOLED having a single light-extraction layer incorporating a single carrier-transport material (i.e., Alq3) has a significantly lower external quantum efficiency than a TEOLED in accordance with the invention having two light-extraction layers, one composed of Alq3 and the other of the aforementioned triaryl amine derivative.

### BRIEF DESCRIPTION OF THE DRAWINGS

FIG. 1 depicts a TEOLED incorporating a light-extraction structure in accordance with the illustrative embodiment of the present invention.

FIG. 2 depicts a first embodiment of the light-extraction structure of the TEOLED of FIG. 1.

FIG. 3 depicts a second embodiment of the light-extraction structure of the TEOLED of FIG. 1.

FIG. 4 depicts a plot of external quantum efficiency for a TEOLED that does not include a light-extraction structure in accordance with the present teachings and for a TEOLED that does.

### DETAILED DESCRIPTION

Definitions. The following terms/phrases and their inflected forms are defined for use in this disclosure and the appended claims as follows:
“carrier-transport material” means electron transport material and/or hole transport material.
“disposed on” means “on or above”. That is, it includes configurations in which, for example, two layers directly touch/abut one another, as well as configurations in which there are intervening layers between two layers in question.

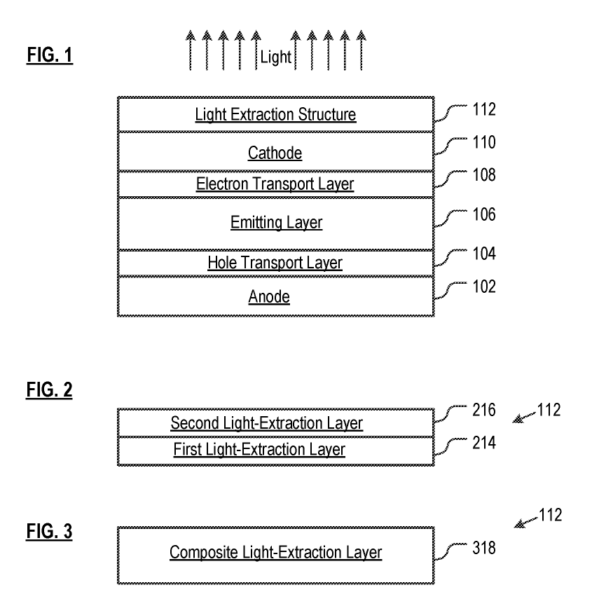

FIG. 1 depicts TEOLED 100 in accordance with an illustrative embodiment of the present invention. TEOLED 100 includes anode 102, hole transport layer 104, emitting layer 106, electron transport layer 108, cathode 110, and light-extraction structure 112.

Anode 102 is a positively charged electrode; it attracts electrons. Hole transport layer 104 typically comprises organic molecules or polymers that transport holes from anode 102. Emitting layer 106 typically comprises small organic molecules or polymers. Commonly used small organic molecules for the emitting layer include organometallic chelates, such as Alq3. Electron transport layer 108 facilitates transport of the electrons. Cathode 110 is a negatively charged electrode; it attracts holes. Since TEOLED 100 is a top emitter, cathode 110 must permit light to pass (i.e., it must semi-transparent). Any of a variety of materials, such as indium tin oxide (ITO), may suitably be used to provide a cathode with the requisite transparency. Layers 102 through 110 are conventional; the materials selection and fabrication thereof is within the capabilities of those skilled in the art.

In basic OLED operation, a voltage is applied across the OLED. Electrons are injected from cathode 110 and holes are injected from anode 102. Under the influence of an electric field, the charges migrate toward emitting layer 106. The charges recombine (exciton formation) and then decay resulting in the emission of photons.

Common losses in efficiency (brightness) associated with light out-coupling are attributable to the internal reflection of the emitted light at the various interfaces within the device, followed by reabsorption and thermalization.

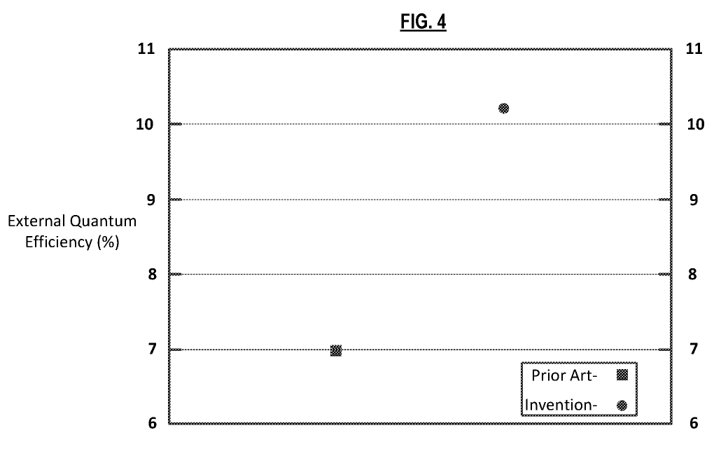

In accordance with the present teachings, TEOLED 100 includes light-extraction structure 112. The light-extraction structure is situated “above” cathode 110. The light-extraction structure provides an anti-reflection functionality based on a selection of materials with appropriate refractive indices. As discussed further below in conjunction with FIGS. 2 and 3, in various embodiments, light-extraction structure 112 comprises carrier-transport materials situated in one or more layers. Based on the carrier-transport materials selected and their respective refractive indices, the light-extraction structure has an effective refractive index that is tuned, by appropriately varying layer thickness, to increase transmissivity (and hence out-coupling) to wavelengths of light generated by the TEOLED. This increases the brightness of the TEOLED relative to a TEOLED that does not possess light-extraction structure 112.

FIG. 2 depicts an embodiment in which light-extraction structure 112 includes two light-extraction layers: first light-extraction layer 214 and second light-extraction layer 216.

In some embodiments, first light-extraction layer 214 consists essentially of electron transport material and second light-extraction layer 216 consists essentially of hole transport material. In some other embodiments, first light-extraction layer 214 consists essentially of hole transport material and second light-extraction layer 216 consists essentially of electron transport material.

In some further embodiments, both the first and second light-extraction layers comprise electron transport material, although the particular electron transport material used in each layer is different. In some additional embodiments, both the first and second light-extraction layers comprise hole transport material, although the particular hole transport material used in each layer is different

In yet some further embodiments, first light-extraction layer 214 consists essentially of a mix of electron transport material and hole transport material, and second light-extraction layer 216 consists essentially of electron transport material and hole transport material. In some of such embodiments, the mix is the same in both layers (i.e., the same electron transport material and the same hole transport material is used although the proportions of the materials will differ between the two layers). In yet some further embodiments, one or both of the electron transport material and the hole transport material are different as between the two light-extraction layers. The thickness of the two light-extraction layers can be the same or different from one another.

In embodiments in which the light-extraction layers 214 or 216 comprise a mix, the portions of electron transport material and hole transport material in the mix can vary based on achieving a desired effective refractive index as necessary to realize a given light transmissivity. Typically, the weight ratio of electron transport material to hole transport material in the composition will vary from 30:70 to 70:30.

In some further embodiments, one of first light-extraction layer 214 or second light-extraction layer 216 consists essentially of a mix of electron transport material and the hole transport material, and the other light-extraction layer 216 or 214 consists essentially of one electron transport material or one hole transport material. In some of such embodiments, the one electron transport material or the one hole transport material is the same as that used in the mix. In some other of such embodiments, the one electron transport material or the one hole transport material is different than that used in the mix.

In still some further embodiments, more than two light-extraction layers are used. For example, in some embodiments, at least one of first light-extraction layer 214 and second light-extraction layer 216 includes a plurality of sub-layers, where each sub-layer is a homogeneous layer of a different carrier-transport material.

In some embodiments, the electron transport material is Alq3 and the hole transport material is a triaryl amine derivative, such as EL-301. EL-301 is characterized by a high glass transition temperature (T_{g}) of 132° C., and has a highest occupied molecular orbital (HOMO) of 5.45 eV and a lowest unoccupied molecular orbital (LUMO) of 2.48 eV.

In embodiments in which one of the light-extraction layers consists essentially of Alq3 and the other of the light-extraction layers consists essentially of EL-301, the combined thickness of the two light-extraction layers is about 120 microns, nominally 60 microns for each layer. For such materials, the combined thickness can range from about 100 to 140 microns.

Based on the carrier-transport materials selected and their respective refractive indices, the light-extraction structure has an effective refractive index that is tuned, by appropriately varying layer thickness, to increase the transmissivity (and hence out-coupling) to wavelengths of light generated by the TEOLED. This increases the brightness of the TEOLED relative to a TEOLED that does not possess light-extraction structure 112. It is within the capabilities of those skilled in the art to determine the requisite layer thickness to accomplish this.

In some embodiments, the second light-extraction layer is formed on the first light-extraction layer. The first and second light-extraction layers can be deposited via thermal deposition using shadow masks, in known fashion. In some alternative embodiments, there are intervening layers between the first light-extraction layer and the second light-extraction layer. The intervening layers must be transmissive, but they need not comprise carrier-transport material.

FIG. 3 depicts an embodiment in which light-extraction structure 112 is a composite light-extraction layer 318. The composite light-extraction layer includes a mixture of hole transport material and electron transport material. In some embodiments, the electron transport material is Alq3 and the hole transport material is a triaryl amine derivative, such as EL-301.

FIG. 4 compares the performance, expressed as the external quantum efficiency, of blue TEOLED having a single light-extraction layer composed of Alq3 and a blue TEOLED in accordance with the invention having two light-extraction layers, one of which composed of Alq3 and the other of EL301. The efficiency of an OLED is typically quantified by a parameter referred to as the external quantum efficiency (EQE). The EQE is defined as the ratio of the number of extracted photons to the number of injected charge carriers.

As depicted, the external quantum efficiency of the inventive device, represented by the “circle” in the plot, is 10.2%, whereas that of TEOLED with the single light-extraction layer with a single carrier-transport material is 6.99%. This represents a 46% improvement in EQE for the inventive device. Thus, compared to the use of a single light-extraction layer consisting essentially of a single carrier-transport material, such as Alq3, this embodiment of the invention increased light out-coupling by creating a light-extraction system having greater light transmissivity as a function of its effective refractive index.

It is to be understood that the disclosure teaches just one example of the illustrative embodiment and that many variations of the invention can easily be devised by those skilled in the art after reading this disclosure.

What is claimed:

1. A top emitting OLED having a hole transport layer, an emitting layer, and an electron transport layer sandwiched between an anode and a cathode, the top emitting OLED further having a light-extraction structure disposed on the cathode, wherein the light-extraction structure comprises at least two carrier-transport materials.

2. The top emitting OLED of claim 1 and further wherein one of the carrier-transport materials is an electron transport material and the second of the at least two carrier-transport materials is a hole transport material.

3. The top emitting OLED of claim 2 and further wherein the electron transport material is Alq3 and the hole transport material is a triaryl amine derivative.

4. The top emitting OLED of claim 1 and further wherein the light-extraction structure comprises a first light-extraction layer and a second light-extraction layer.

5. The top emitting OLED of claim 4 and further wherein the first light-extraction layer consists essentially of one of either electron transport material or hole transport material.

6. The top emitting OLED of claim 5 and further wherein the electron transport material is Elq3 and the hole transport material is a triaryl amine derivative.

7. The top emitting OLED of claim 4 and further wherein the second light-extraction layer consists essentially of one of either an electron transport material or a hole transport material.

8. The top emitting OLED of claim 7 and further wherein electron transport material is Elq3 and the hole transport material is a triaryl amine derivative.

9. The top emitting OLED of claim 4 and further wherein:
the first light-extraction layer consists essentially of a mix of an electron transport material and a hole transport material; and
the second light-extraction layer consists essentially of a mix of the electron transport material and the hole transport material, wherein the amount of at least one of either the electron transport material or the hole transport material is different in the two light-extraction layers.

10. The top emitting OLED of claim 4 and further wherein the electron transport material is Elq3 and the hole transport material is a triaryl amine derivative.

11. The top emitting OLED of claim 4 and further wherein:
the first light-extraction layer consists essentially of a first mix having a first electron transport material and a first hole transport material; and
the second light-extraction layer consists essentially of a second mix of an electron transport material and a hole transport material, wherein at least one of the electron transport material and the hole transport material in the second mix is different from the first electron transport material and the first hole transport material in the first mix.

12. The top emitting OLED of claim 4 and further wherein:
one of the first light-extraction layer or the second light-extraction layer consists essentially of a mix of an electron transport material and a hole transport material; and
the other of the first light-extraction layer or second light-extraction layer consists essentially of one of an electron transport material or a hole transport material.

13. The top emitting OLED of claim 4 and further wherein at least one of first light-extraction layer or second light-extraction layer includes a plurality of sub-layers, wherein each sub-layer is a homogeneous layer consisting essentially of a different carrier-transport material.

14. The top emitting OLED of claim 13 and further wherein a first sub-layer of the plurality thereof comprises Alq3 and a second sub-layer of the plurality thereof comprises a triaryl amine derivative.

15. The top emitting OLED of claim 1 and further wherein the light-extraction layer consists essentially of a mix of an electron transport material and a hole-transport material.

16. The top emitting OLED of claim 15 and further wherein the electron transport material is Alq3.

17. The top emitting OLED of claim 15 and further wherein the hole transport material is a triaryl amine derivative.

18. A top emitting OLED comprising:
a first light-extraction layer disposed on a cathode;
a second light-extraction layer disposed on the first light-extraction layer, wherein:
at least one of the first light-extraction layer or the second light-extraction layer comprises Alq3; and
at least one of the first light-extraction layer or the second light-extraction layer comprises a triaryl amine derivative.

19. A method for making a top emitting OLED, the method comprising forming a first light-extraction structure on a cathode of the top emitting OLED, wherein the light-extraction structure comprises at least two carrier-transport materials.

20. The method of claim 19 wherein forming a first light-extraction structure further comprises:
forming a first light-extraction layer on the cathode;
disposing a second light-extraction layer on the first light-extraction layer.
